(19) United States
(12) Patent Application Publication
(10) Pub. No.: US 2026/0313790 A1
(43) Pub. Date: Oct. 8, 2026

(54) WIRING SUBSTRATE

(71) Applicant: IBIDEN CO., LTD., Gifu (JP)

(72) Inventors: Jun SAKAI, Gifu (JP); Ramesh BHANDARI, Gifu (JP)

(73) Assignee: IBIDEN CO., LTD., Gifu (JP)

(21) Appl. No.: 19/341,187

(22) Filed: Sep. 26, 2025

(30) Foreign Application Priority Data
Sep. 27, 2024 (JP) 2024-168239

(51) Int. Cl. H05K 1/02

(52) U.S. Cl. CPC H05K 1/0298

(57) ABSTRACT

A wiring substrate includes a wiring substrate having a cavity, and multiple wiring structures accommodated in the cavity of the substrate and including at least two of a first wiring structure, a second wiring structure and a third wiring structure. The structures include relay lines internally incorporated and having connection points exposed on upper surfaces of the structures at the end portions of the relay lines. The first structure includes a silicon layer in a lower part of the first structure, the second structure includes a glass layer in a lower part of the second structure, the third structure includes a resin layer and does not include a glass layer or a silicon layer in a lower part of the third structure, and the at least two of the first, second and third structures differ in at least one of planar size and in minimum L/S of the relay lines.

### CROSS-REFERENCE TO RELATED APPLICATIONS

The present application is based upon and claims the benefit of priority to Japanese Patent Application No. 2024-168239, filed Sep. 27, 2024, the entire contents of which are incorporated herein by reference.

### BACKGROUND OF THE INVENTION

### Field of the Invention

The present invention relates to a wiring substrate.

### Description of Background Art

Japanese Patent Application Laid-Open Publication No. 2014-236188 describes a wiring substrate in which a wiring structure called a patch is embedded. The entire contents of this publication are incorporated herein by reference.

### SUMMARY OF THE INVENTION

According to one aspect of the present invention, a wiring substrate includes a wiring substrate having a cavity, and multiple wiring structures accommodated in the cavity of the wiring substrate and including at least two of a first wiring structure, a second wiring structure and a third wiring structure such that the wiring structures include relay lines internally incorporated and having connection points exposed on upper surfaces of the wiring structures at end portions of the relay lines. The first wiring structure includes a silicon layer in a lower part of the first wiring structure, the second wiring structure includes a glass layer in a lower part of the second wiring structure, the third wiring structure includes a resin layer and does not include a glass layer or a silicon layer in a lower part of the third wiring structure, and the at least two of the first, second and third wiring structures differ in at least one of in planar size and minimum L/S of the relay lines.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional side view of a wiring substrate according to an embodiment of the present invention;

FIG. 2 is a plan view of a wiring substrate according to an embodiment of the present invention;

FIGS. 3A and 3B are plan views of electronic components according to an embodiment of the present invention;

FIGS. 4A, 4B, and 4C are plan views of wiring structures according to embodiments of the present invention;

FIGS. 5A, 5B, and 5C are cross-sectional side views of wiring structures according to embodiments of the present invention;

FIG. 6A is a cross-sectional side view of a wiring substrate before a cavity is formed according to an embodiment of the present invention;

FIG. 6B is a cross-sectional side view of a wiring substrate with a cavity formed according to an embodiment of the present invention;

FIG. 6C is a cross-sectional side view of a wiring substrate with wiring structures formed in the cavity according to an embodiment of the present invention;

FIG. 7A is a cross-sectional side view of a wiring substrate with via holes formed in an outermost insulating layer according to an embodiment of the present invention;

FIG. 7B is a cross-sectional side view of a wiring substrate with via conductors formed in the via holes according to an embodiment of the present invention;

FIG. 7C is a cross-sectional side view of a wiring substrate with metal posts formed according to an embodiment of the present invention;

FIG. 8 is a cross-sectional side view of a wiring substrate according to an embodiment of the present invention;

FIG. 9 is a plan view of a wiring substrate according to an embodiment of the present invention; and

FIGS. 10A, 10B, and 10C are plan views of wiring structures according to embodiments of the present invention.

### DETAILED DESCRIPTION OF THE EMBODIMENTS

Embodiments will now be described with reference to the accompanying drawings, wherein like reference numerals designate corresponding or identical elements throughout the various drawings.

### First Embodiment

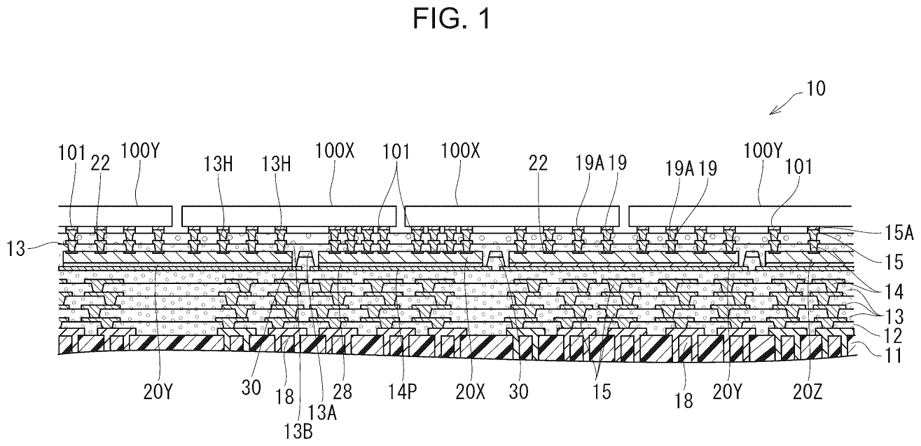

With reference to FIGS. 1 to 5, a wiring substrate 10 according to an embodiment of the present invention is described. The wiring substrate 10 illustrated in FIG. 1 is a multilayer wiring substrate, and includes a build-up part 12 in which multiple insulating layers 13 and multiple conductive layers 14 are alternately laminated on both front and back surfaces of a core substrate 11. FIG. 1 illustrates an enlarged view of only a portion on the front surface side of the core substrate 11 of the wiring substrate 10.

Each insulating layer 13 includes multiple via conductors 15, and the via conductors 15 connect conductive layers 14 adjacent to each other with the insulating layer 13 interposed therebetween in the build-up part 12. The core substrate 11 includes multiple through-hole conductors 18, and the through-hole conductors 18 connect the innermost conductive layers 14 to each other.

Among the insulating layers 13 and the conductive layers 14, the outermost layer farthest from the core substrate 11 is, for example, a conductive layer 14. Further, the insulating layer 13 located one layer inside the outermost insulating layer 13 has a two-layer structure in which a lower insulating layer (13A) and an upper insulating layer (13B) are laminated. Further, a part of the fifth conductive layer 14 as counted from the core substrate 11 side is a solid plane layer (14P).

Among multiple openings (13H) formed in the outermost insulating layer 13, metal posts 19 are provided in all of the openings illustrated in FIG. 1, and the via conductors 15 are also provided directly beneath the metal posts 19, forming a stacked structure.

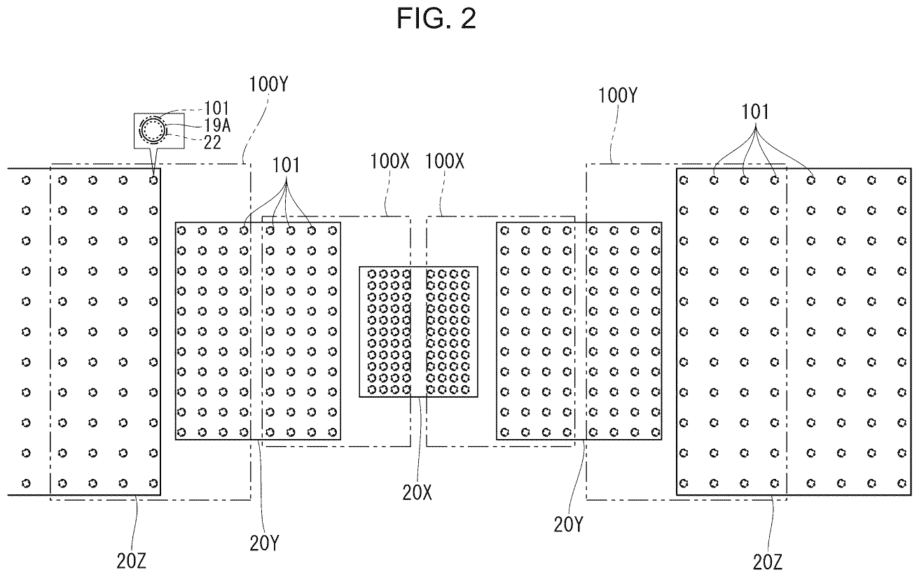

Upper surfaces of the multiple metal posts 19 serve as multiple pads (19A). The multiple pads (19A) are formed on the same plane and, as illustrated in FIG. 2, are divided into multiple regions and formed in a matrix pattern in each of the regions.

As illustrated in FIG. 2, mounted components of the wiring substrate 10 include multiple chip-type electronic components (100X, 100Y, . . . ) having multiple pads 101 formed in a matrix pattern on their lower surfaces. These multiple electronic components (100X, 100Y, . . . ) are, for example, semiconductor elements, and include multiple types with different functions such as CPU elements, memory elements, and sensor elements. The multiple pads 101 of the multiple electronic components (100X, 100Y, . . . ) are flip-chip connected to the multiple pads (19A) described above. Hereinafter, when not distinguishing among the electronic components (100X, 100Y, . . . ) they are collectively referred to as the electronic components 100.

In FIG. 2, outlines and pads 101 of the electronic components 100 are illustrated with imaginary lines (two-dot chain lines), the pads (19A) are illustrated with solid lines, and outlines and connection points 22 of wiring structures 20, which will be described later, are illustrated with dashed lines. Since lines indicating the connection points 22 and the pads (19A, 101) are difficult to distinguish, some of the connection points 22 and the pads (19A, 101) are illustrated in an enlarged manner at the upper left of FIG. 2. Further, in order to prevent the lines indicating the connection points 22 and the pads (19A, 101) from overlapping, their sizes are made different. However, planar shapes of the connection points 22 and the pads (19A, 101) may be the same or different.

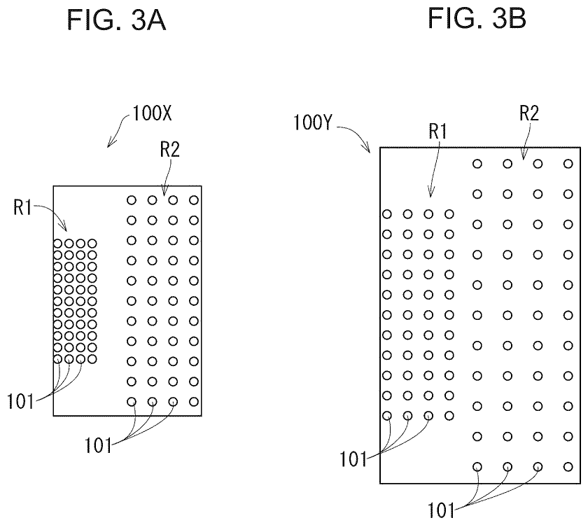

The electronic components 100 each have a rectangular planar shape, and, as described above, the multiple pads 101 are formed in a matrix pattern over the entire lower surface. Further, a pitch of the multiple pads 101 (hereinafter referred to as a “pad pitch”) differs between some regions of each electronic component 100. Specifically, as illustrated in FIGS. 3A and 3B, each electronic component 100 is provided with a first region (R1) formed closer to one of a pair of opposing outer edges and a second region (R2) formed closer to the other, and the pad pitch of the second region (R2) is larger than the pad pitch of the first region (R1). The second region (R2) of the electronic component (100X) and the first region (R1) of the electronic component (100Y) have the same pad pitch. That is, in ascending order of the pad pitches, the order is: the first region (R1) of the electronic component (100X); followed by the second region (R2) of the electronic component (100X) and the first region (R1) of the electronic component (100Y); and then the second region (R2) of the electronic component (100Y).

As illustrated in FIG. 2, for example, the above-described multiple electronic components 100 are uniformly oriented such that their vertical and horizontal outer edges are parallel or perpendicular to each other and are symmetrically formed such that a pair of electronic components (100X) is sandwiched by a pair of electronic components (100Y). Further, adjacent electronic components 100 are formed such that regions with the same pad pitch are positioned near the respective outer edges. The multiple pads (19A) on an upper surface of the wiring substrate 10 are located directly beneath the pads 101 of the multiple electronic components 100.

In the wiring substrate 10 of the present embodiment, the multiple electronic components 100 are formed symmetrically. However, the multiple electronic components 100 may be formed arbitrarily and do not have to be formed symmetrically, and the orientations of the multiple electronic components 100 do not have to be unified. Further, the electronic components 100 described above may each be a standalone semiconductor chip, or a semiconductor chip package in which an interposer substrate and a semiconductor chip are combined. That is, any semiconductor component for surface mounting may be used. Further, although BGA (Ball Grid Array) type components are assumed as the electronic components 100 in the present embodiment, LGA (Land Grid Array) type components may also be used.

In order to connect the multiple pads 101 of adjacent electronic components 100 among the multiple electronic components 100 illustrated in FIG. 2, three types of wiring structures, namely first to third wiring structures (20X, 20Y, 20Z), are embedded in an upper part of the build-up part 12 on an upper side of the wiring substrate 10. When the first to third wiring structures (20X, 20Y, 20Z) are not distinguished, they are collectively referred to as the wiring structures 20. First, a structure common to all of the wiring structures 20 will be described.

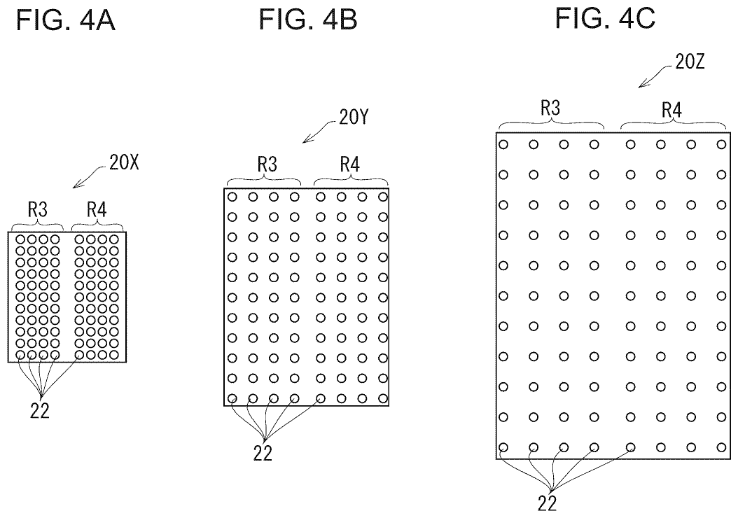

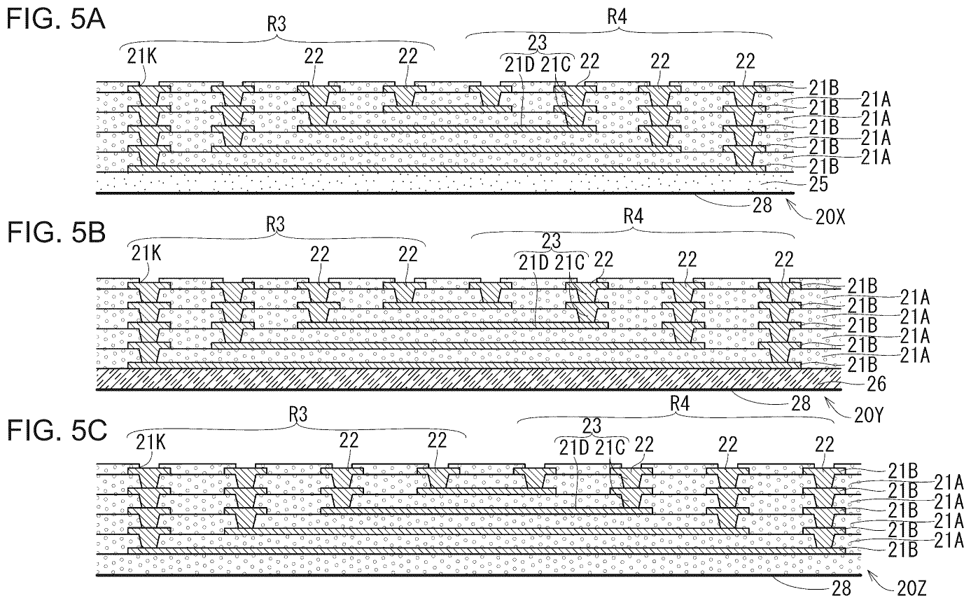

As illustrated in FIGS. 4A to 4C, the wiring structures 20 each have, for example, a plate shape having a rectangular planar shape. Further, as illustrated in FIGS. 5A to 5C, multiple relay lines 23 are embedded inside the wiring structures 20. Further, both ends of the multiple relay lines 23 are exposed on upper surfaces of the wiring structures 20 as the multiple connection points 22. The multiple connection points 22 are divided and formed into a first array region (R3) corresponding to a first region (R1) of two adjacent electronic components 100, and a second array region (R4) corresponding to a second region (R2).

Further, in the first array region (R3) and the second array region (R4), the pitch between the connection points 22 is constant. Further, as illustrated in FIG. 1, the connection points 22 and the pads 101 that overlap in a vertical direction are connected via the metal posts 19 described above.

As illustrated in FIG. 1, the wiring substrate 10 is provided with a cavity 30 that penetrates through the lower insulating layer (13A) of the outermost insulating layer 13 and the insulating layer 13 thereunder, and has the plane layer (14P) as its bottom surface. Further, the cavity 30 is divided into three cavities: one cavity 30 that collectively accommodates a pair of first wiring structures (20X) and a pair of second wiring structures (20Y), and cavities 30 that each accommodate a third wiring structure (20Z). All of the wiring structures 20 may be collectively accommodated in one cavity 30, or each wiring structure 20 may be accommodated in one cavity 30.

Each wiring structure 20 is accommodated with its lower surface overlapping a bottom surface of the cavity 30. Further, the upper surface of each wiring structure 20 is covered by the upper insulating layer (13B) of the outermost insulating layer 13, and resin constituting the upper insulating layer (13B) fills a gap between an inner surface of the cavity 30 and the wiring structure 20, thereby fixing the wiring structure 20 in the cavity 30. Then, via the via conductors 15 formed in the upper insulating layer (13B) and the insulating layer 13 that covers the upper insulating layer (13B) from above, the metal posts 19 are connected to the connection points 22 of the wiring structures 20. Upper ends of the multiple metal posts 19 serve as the pads (19A) described above and are connected to the multiple pads 101 of the electronic components 100. That is, the connection points 22 of the wiring structures 20 and the pads 101 of the electronic components 100 that overlap in the vertical direction are connected via the metal posts 19.

As illustrated in FIG. 1, some of the multiple metal posts 19 are formed on a side opposite to the second wiring structure (20Y) with respect to each third wiring structure (20Z), and are connected to the third conductive layer 14 from the top of the wiring substrate 10 via the via conductors 15. Further, the pads (19A) at the upper ends of those multiple metal posts 19 are connected to the multiple pads 101 located on the lower surface of a portion of the electronic component (100Z) that is offset from above the third wiring structure (20Z).

When the insulating layer 13 having its upper surface positioned at the bottom of the cavity 30 is referred to as a “first insulating layer,” and the lower insulating layer (13A) is referred to as a “third insulating layer,” then the wiring substrate 10 of the present embodiment has a structure in which “a multilayer structure in which a first insulating layer, a first conductive layer, a second insulating layer, a second conductive layer, a third insulating layer, and a third conductive layer are sequentially laminated from bottom to top is provided, and a cavity for accommodating the wiring structures is formed so as to penetrate both the second insulating layer and the third insulating layer.”

The details of the wiring structures 20 are as follows. The first wiring structure (20X) may be referred to as a silicon patch and includes, at its lowermost part, a silicon layer 25 as a support layer. The second wiring structure (20Y) may be referred to as a glass patch and includes, at its lowermost part, a glass layer 26 as a support layer. The third wiring structure (20Z) may be referred to as a resin patch and has a structure that does not include a support layer, that is, a structure that does not include a glass layer or a silicon layer. An adhesive layer 28 is affixed to the lower surface of each wiring structure 20 to fix the wiring structure 20 to the bottom of the cavity 30.

Specifically, as illustrated in FIG. 5A, the first wiring structure (20X) includes conductive layers (21B) and insulating layers (21A) alternately laminated on the silicon layer 25, with the uppermost layer being an insulating layer (21A). In each conductive layer (21B), for example, multiple lines (21D) are provided that do not intersect with each other (in FIG. 5A, the lines (21D) in the uppermost layer are omitted). On both ends of each line (21D) in the layers below the uppermost layer, one- or multi-stage via conductors (21C) that penetrate one or multiple insulating layers (21A) are provided, and among those via conductors (21C), the via conductors (21C) of the uppermost stage are connected to the uppermost conductive layer (21B). The above relay lines 23 are constituted either by the lines (21D) of the uppermost layer alone, or by the lines (21D) of the layers below the topmost layer together with the via conductors (21C) on both ends thereof and with a portion of the uppermost conductive layer (21B) on the via conductors (21C). Both ends of each relay line 23 are exposed on the first wiring structure (20X) through through holes (21K) formed in the uppermost insulating layer (21A), forming the connection points 22 described above.

As illustrated in a simplified form in FIGS. 5B and 5C, the second and third wiring structures (20Y, 20Z) have basically the same structure as the first wiring structure (20X), except that the glass layer 26 is provided in place of the silicon layer 25, or that neither the silicon layer 25 nor the glass layer 26 is provided.

Planar sizes of the wiring structures 20 decrease in the order of the first wiring structure (20X), the second wiring structure (20Y), and the third wiring structure (20Z). Further, a minimum L/S value of the lines (21D) decreases in the order of the first wiring structure (20X), the second wiring structure (20Y), and the third wiring structure (20Z). Specifically, the line width (L) of each of the lines (21D) is 0.5 to 2 μm in the first wiring structure (20X), 2 to 3 μm in the second wiring structure (20Y), and 3 to 5 μm in the third wiring structure (20Z). Further, the inter-line spacing width(S) of the lines (21D) is 0.5 to 2 μm in the first wiring structure (20X), 2 to 3 μm in the second wiring structure (20Y), and 3 to 5 μm in the third wiring structure (20Z).

In the wiring substrate 10 of the present embodiment, the multiple wiring structures 20 are formed symmetrically. However, the wiring structures 20 do not have to be formed symmetrically, and the orientations of the multiple wiring structures 20 do not have to be unified. Further, although three types of wiring structures 20 are provided in the wiring substrate 10, the types of wiring structures 20 provided in the wiring substrate 10 may be two types, or four or more types. Further, not all of the electronic components 100 have to be connected by the wiring structures 20. For example, some of the pads 101 of the electronic components 100 may be connected to the third conductive layer 14 from the top of the wiring substrate 10 via the metal posts 19 and the via conductors 15.

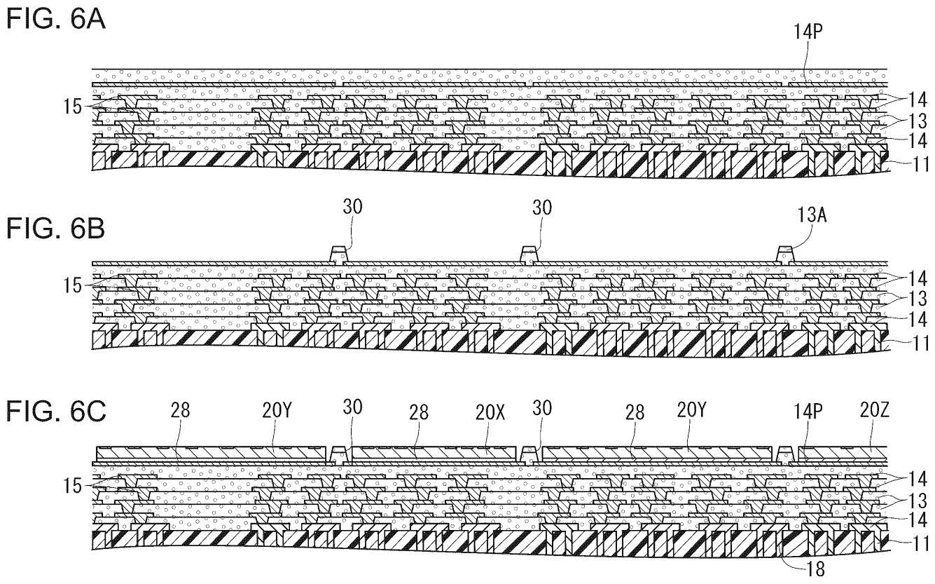

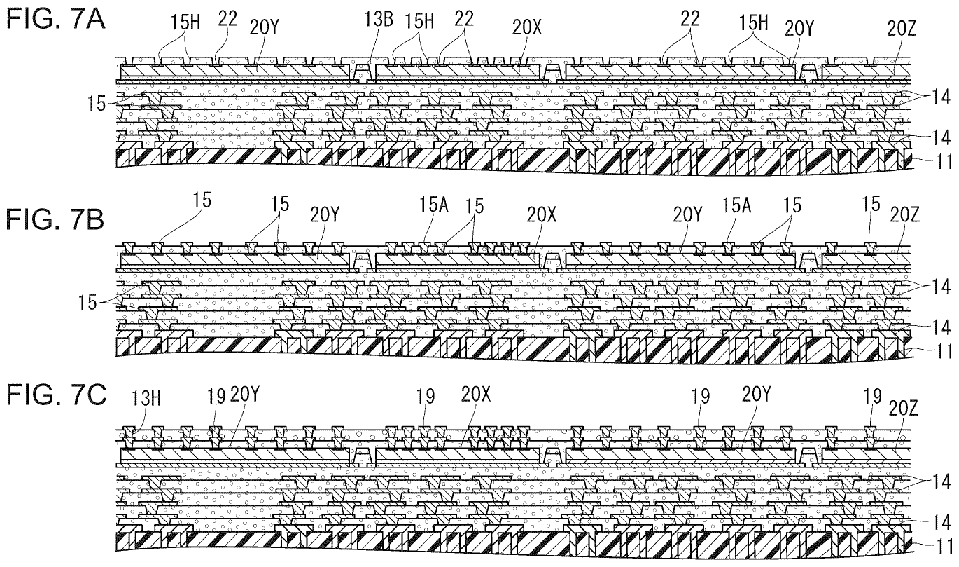

The description about the wiring substrate 10 of the present embodiment is as given above. Next, with reference to FIGS. 6A to 6C and 7A to 7C, a method for manufacturing a wiring substrate according to an embodiment of the present invention is described.

The core substrate 11 is prepared. The core substrate 11 is a core substrate in which the through-hole conductors 18 and conductive layers 14 are formed in or on a structure in which copper foils are laminated on both sides of a glass cloth impregnated with resin. Next, an insulating layer 13 may be laminated on the core substrate 11, and a conductive layer 14 may be laminated thereon using, for example, a semi-additive method. Subsequently, using the same method, six insulating layers 13 and six conductive layers 14 are alternately laminated. In this case, in the fifth conductive layer 14 counted from the core substrate 11 side, the solid plane layer (14P) is formed. Further, the multiple via conductors 15 are formed in the multiple insulating layers 13 (see FIG. 6A).

An insulating layer 13 is further laminated. This insulating layer 13 corresponds to the lower insulating layer (13A) of the outermost insulating layers 13. Next, a portion of the lower insulating layer (13A) that is laminated on the plane layer (14P) is irradiated with CO2 laser, and the cavity 30 penetrating the lower insulating layer (13A) and an adjacent insulating layer 13 is formed (see FIG. 6B).

The wall surfaces and bottom surface of the cavity 30 are desmeared by a permanganate treatment, and the surface of the plane layer (14P) is subjected to a CZ treatment. Next, the wiring structures 20 are formed in the cavity 30. These wiring structures 20 are heated and pressed using a bonding head (not illustrated), and the adhesive layer 28 on the lower surface of the wiring structures 20 adheres to the plane layer (14P) (see FIG. 6C).

When an insulating resin film (for example, ABF) is laminated onto the upper surfaces of the wiring structures 20 and the cavity 30 and heated and pressed, the molten resin flows into gaps between the side surfaces of the wiring structures 20 and the wall surfaces of the cavity 30, and the upper insulating layer (13B) of the outermost insulating layers 13 is laminated. Next, UV laser is irradiated toward portions of the outermost insulating layer 13 that are laminated on the multiple connection points 22 of the wiring structures 20, and multiple via holes (15H) are formed (see FIG. 7A).

An electroless plating treatment, a plating resist treatment, and an electrolytic plating treatment are performed, and when the plating resist is removed, a conductive layer 14 is laminated on the insulating layer 13, via conductors 15 are formed in the via holes (15H), and via lands (15A) are formed at upper ends of the via conductors 15 (see FIG. 7B).

Further, an outermost insulating layer 13 serving as a solder resist layer is laminated on the conductive layer 14, and openings (13H) that expose the via lands (15A) of the via conductors 15 may be formed using a method such as photolithography. Next, an electroless plating treatment, a plating resist treatment, and an electrolytic plating treatment are sequentially performed on the outermost insulating layer 13, and when the plating resist is removed, the metal posts 19 are formed in the openings (13H), and the pads (19A) at the upper ends of the metal posts 19 are formed on the upper surfaces of the metal posts 19 (see FIG. 7C).

After the electronic components 100 are mounted on the metal posts 19 by a chip mounter (not illustrated), a reflow treatment is performed, and the electronic components 100 are mounted on the metal posts 19.

In the present embodiment, the metal posts 19 are formed by plating. However, instead of the metal posts 19, solder may be formed in the openings (13H).

The description about the method for manufacturing the wiring substrate 10 is as given above. According to the structure of the wiring substrate 10 of the present embodiment, the following effects can be achieved. With current technology, an achievable minimum L/S value and an achievable maximum planar size differ between the three types of wiring structures 20: the first wiring structure (20X) that includes the silicon layer 25, the second wiring structure (20Y) that includes the glass layer 26, and the third wiring structure (20Z) that includes neither a silicon layer nor a glass layer. Further, with current technology, in the order of the first, second, and third wiring structures (20X, 20Y, 20Z), the achievable minimum L/S value becomes smaller, and the achievable maximum planar size becomes smaller.

On the other hand, the electronic components 100 mounted on the wiring substrate 10 have diverse requirements depending on their types, such as a degree of high integration demanded or a degree of planar size enlargement demanded. However, for example, even when attempting to make wirings of the wiring structures 20 finer to meet the needs of the electronic components 100 having a large number of densely formed pads, it may be difficult for a wiring structure that includes a glass layer or a wiring structure that does not include a support layer to meet the demand for high integration. Further, even when attempting to enlarge the wiring structures 20 in order to mount large electronic components 100, it is difficult to increase the planar size of a wiring structure that includes a silicon layer formed by cutting from a circular silicon wafer, and even when enlargement is achieved, such a wiring structure is prone to breakage and thus has a durability problem. That is, when attempting to mount multiple types of electronic components 100 on a wiring substrate 10 having only one type of wiring structure 20, problems such as reduced durability may occur.

In contrast, the wiring substrate 10 of the present embodiment includes two or more types of wiring structures 20, such as the first to third wiring structures (20X, 20Y, 20Z), which differ in planar size and minimum L/S value. Therefore, it is possible to mount multiple types of electronic components 100 having different requirements for high integration.

### Second Embodiment

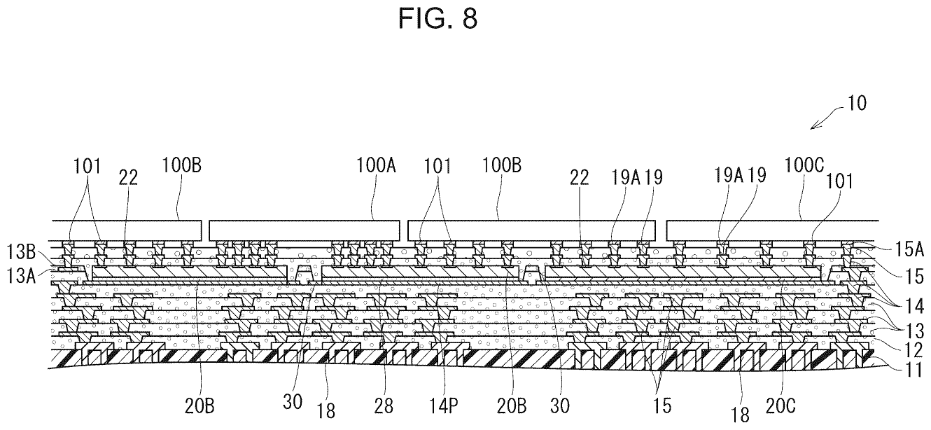

In the above first embodiment, the multiple electronic components 100 are each provided with a first region (R1) and a second region (R2) having different pad pitches, and the first regions (R1) and the second regions (R2) of adjacent electronic components 100 were connected by the wiring structures 20. In each wiring structure 20, in order to align the connection points 22 with the pads 101, the pitch of the multiple connection points 22 formed in the first array region (R3) is the same as that in the second array region (R4). The present embodiment differs significantly from the above embodiment in that the pitch of the multiple connection points 22 differs between the first array region (R3) and the second array region (R4). In the following, with reference to FIGS. 8 to 12, only the differences from the first embodiment are described.

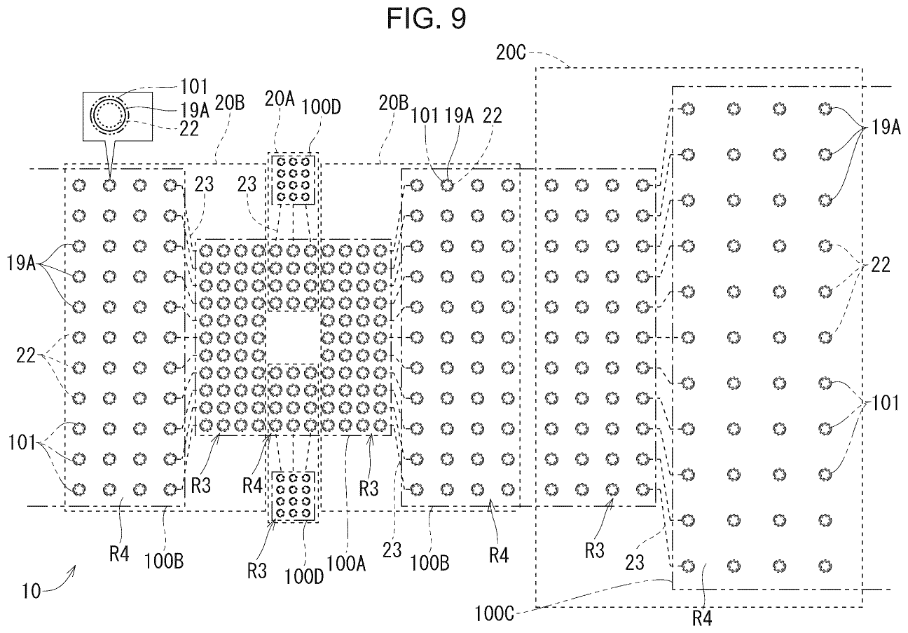

As illustrated in FIG. 9, electronic components (100A, 100B, 100C, 100D) are mounted on the wiring substrate 10 of the present embodiment. With respect to the electronic components 100 except for the electronic component (100A), multiple pads 101 are formed in a matrix pattern over the entire lower surface, while in the case of the electronic component (100A), for example, multiple pads 101 are formed in a matrix pattern over substantially the entire lower surface except for a central rectangular region. Further, the pitch of the pads 101 of each electronic component 100 differs depending on the type of the electronic component 100, and for example, the pitch decreases in the order of the electronic components (100D, 100A, 100B, 100C).

Further, regarding planar sizes of the pads 101, the pads 101 of the electronic components (100A, 100B, 100C) other than the electronic component (100D) have substantially the same planar size, whereas the pads 101 of the electronic component (100D) have a smaller planar size. Further, in the present embodiment, a planar size relationship between the electronic components (100A, 100B, 100C, 100D) is, for example, the same as the pad pitch size relationship described above. That is, for example, the planar size decreases in the order of the electronic components (100D, 100A, 100B, 100C).

As illustrated in FIG. 9, the pad pitches are different between the adjacent electronic components (100A, 100B) and between the adjacent electronic components (100B, 100C). Therefore, the multiple connection points 22 of the wiring structures 20 connected to the multiple pads 101 of these electronic components 100 have different pitches between the first array region (R3) and the second array region (R4), with the pitch of the second array region (R4) being larger than the pitch of the first array region (R3).

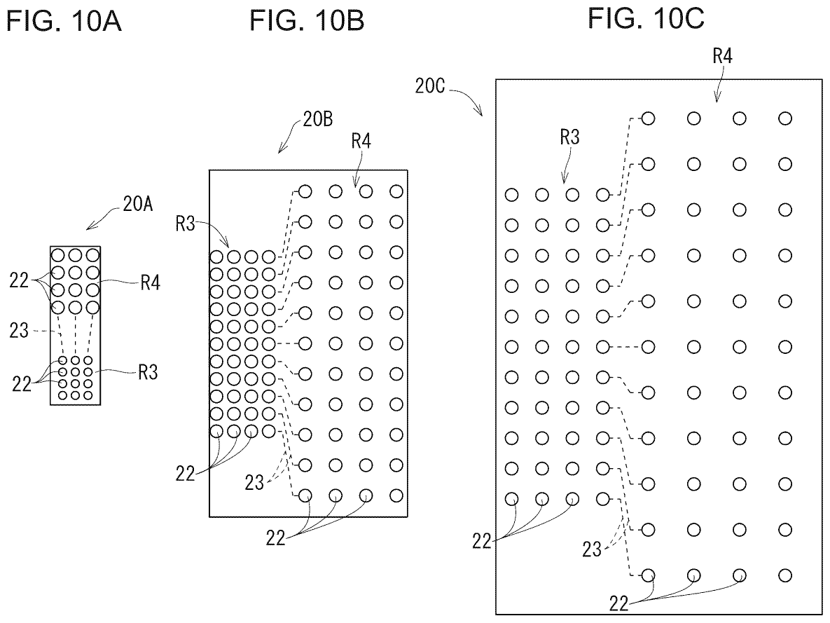

Specifically, the pitch of the connection points 22 (hereinafter referred to as the “connection point pitch” as appropriate) is the same between the second array region (R4) of the first wiring structure (20A) and the first array region (R3) of the second wiring structure (20B) (see FIGS. 10A and 10B), and is the same between the second array region (R4) of the second wiring structure (20B) and the first array region (R3) of the third wiring structure (20C) (see FIGS. 10B and 10C). That is, the connection point pitch is smallest in the first array region (R3) of the first wiring structure (20A), followed by the second array region (R4) of the first wiring structure (20A) and the first array region (R3) of the second wiring structure (20B), then the second array region (R4) of the second wiring structure (20B) and the first array region (R3) of the third wiring structure (20C), and largest in the second array region (R4) of the third wiring structure (20C). Further, regarding the planar sizes of the wiring structures 20, the first wiring structure (20A) is the smallest, followed by the second wiring structure (20B), and the third wiring structure (20C) is the largest.

In FIG. 9, a pair of second wiring structures (20B) are symmetrically formed on both left and right sides across a central region that is directly beneath a portion of the electronic component (100A) where no pads 101 are provided, and a pair of third wiring structures (20C) are respectively formed adjacent to the pair of second wiring structures (20B) on opposite sides with respect to the central region (in FIG. 9, only one of the third wiring structures (20C) is illustrated). Further, a pair of first wiring structures (20A) are formed symmetrically above and below the central region in FIG. 9. That is, a pair of first wiring structures (20A), a pair of second wiring structures (20B), and a pair of third wiring structures (20C) are formed symmetrically around the central region.

Then, as illustrated in FIG. 8, the multiple connection points 22 of the second array regions (R4) of the pair of first wiring structures (20A) and the multiple connection points 22 of the first array regions (R3) of the pair of second wiring structures (20B) are formed at positions directly beneath the multiple pads 101 of the electronic component (100A), the multiple connection points 22 of the second array region (R4) of each second wiring structure (20B) and the multiple connection points 22 of the first array region (R3) of a third wiring structure (20C) adjacent to the second wiring structure (20B) are formed at positions directly beneath the multiple pads 101 of an electronic component (100B), and further, the multiple connection points 22 of the second array region (R4) of each third wiring structure (20C) are formed at positions directly beneath the multiple pads 101 of an electronic component (100C) on a side near an electronic component (100B).

According to the wiring structures 20 of the second embodiment, since the pitch of the connection points 22 differs between the first array region (R3) and the second array region (R4), electronic components 100 having different pitches of the pads 101 can be connected to each other via the wiring structures 20.

Further, as in the relationship between the first and second wiring structures (20A, 20B) or the relationship between the second and third wiring structures (20B, 20C), by making the pitch of the connection points 22 the same between the second array region (R4) of one wiring structure 20 and the first array region (R3) of the other wiring structure 20, electronic components 100 having mutually different pad 101 pitches can be connected to each other via the wiring structures 20.

Further, in the wiring substrate 10 of the present embodiment, the pitch of the connection points 22 of the first, second, and third wiring structures (20A, 20B, 20C) increases in two stages. That is, the pitch of the connection points 22 is the same between the second array region (R4) of the first wiring structure (20A) and the first array region (R3) of the second wiring structure (20B), and is also the same between the second array region (R4) of the second wiring structure (20B) and the first array region (R3) of the third wiring structure (20C). In this way, by adopting a structure in which the pitch of the connection points 22 increases in multiple stages among three or more types of wiring structures 20, three or more types of electronic components 100 having different pitches of the pads 101 can be connected to each other via the multiple wiring structures 20.

### Other Embodiments

In the above embodiments, all of the first, second, and third wiring structures (20X, 20Y, 20Z) were provided. However, it is also possible that only two of these three types are provided. For example, it is also possible that the wiring substrate 10 is provided with only the first and second wiring structures (20X, 20Y), with the minimum L/S value of the relay lines 23 and the planar size decreasing in the order of the first and second wiring structures (20X, 20Y). Further, it is also possible that the wiring substrate 10 is provided with only the second and third wiring structures (20Y, 20Z), with the minimum L/S value of the multiple relay lines 23 and the planar size decreasing in the order of the second and third wiring structures (20Y, 20Z). Further, it is also possible that the wiring substrate 10 is provided with only the first and third wiring structures (20X, 20Z), with the minimum L/S value of the multiple relay lines 23 and the planar size decreasing in the order of the first and third wiring structures (20X, 20Z).

Further, it is also possible that wiring structures (20X, 20Y, 20Z) in which the pitch of all connection points 22 is the same and wiring structures (20A, 20B, 20C) in which the pitch differs between the first array region (R3) and the second array region (R4) coexist.

As described above, with current technology, in the order of the first wiring structure (20X) containing the silicon layer 25, the second wiring structure (20Y) containing the glass layer 26, and the third wiring structure (20Z) containing neither a silicon layer nor a glass layer, the achievable minimum L/S value decreases and the achievable maximum planar size decreases. However, the minimum L/S and planar size of the first, second, and third wiring structures (20X, 20Y, 20Z) provided in the wiring substrate 10 do not have to follow the achievable order. Among the multiple types of wiring structures 20 provided on the wiring substrate 10, as long as at least one of the minimum L/S or the planar size differs between two types of wiring structures 20, the minimum L/S values and planar sizes of wiring structures 20 of different types may be the same, or may even be in a reverse order of what is achievable.

Specifically, the L/S value of the relay lines 23 may be the same between the wiring structure (20X) provided with the silicon layer 25 and the wiring structure (20Y) provided with the glass layer 26, or the planar size may be the same between the wiring structure (20Y) provided with the glass layer 26 and the wiring structure (20Z) provided with neither the silicon layer 25 nor the glass layer 26. Further, for example, the minimum L/S value of the wiring structure (20Y) provided with the glass layer 26 may be smaller than that of the wiring structure (20X) provided with the silicon layer 25, or the planar size of the wiring structure (20Z) provided with neither the silicon layer 25 nor the glass layer 26 may be smaller than that of the wiring structure (20Y) provided with the glass layer 26. That is, taking into account factors such as the types of electronic components 100 to be mounted and the space available for forming the wiring structures 20, it is possible to select a most suitable wiring structure 20 from those that include a silicon layer 25, a glass layer 26, or neither a silicon layer 25 nor a glass layer 26.

In the above embodiments, as illustrated in FIG. 2, an electronic component (100Y) formed to the right of an electronic component (100X) and an electronic component (100Y) formed to the left of the electronic component (100X) are respectively individually connected by two second wiring structures (20Y). However, it is also possible that they are connected by one second wiring structure (20Y) extending from the right electronic component (100Y) to the left electronic component (100Y). Specifically, the relay lines 23 connecting the electronic component (100X) and the right electronic component (100Y) and the relay lines 23 connecting the electronic component (100X) and the left electronic component (100Y) may be formed together within a second wiring structure (20Y).

The multiple relay lines 23 of each wiring structure 20 in the above embodiments are structured to relay between some of the pads 101 of two electronic components 100. However, for example, it is also possible that the relay lines 23 are structured to relay between all pads 101 of one electronic component 100 and some of the pads 101 of the other electronic component 100. Further, each wiring structure 20 in the above embodiments is structured to relay between two electronic components 100. However, it is also possible that each wiring structure 20 is structured to relay between the pads 101 of three or more electronic components 100.

It is also possible that on the wiring structures 20, two or more insulating layers 13 are laminated, or only one insulating layer 13 is laminated. Further, it is also possible that adjacent wiring structures 20 are formed at different heights in a lamination direction.

It is also possible that the wiring structures 20 do not each have a laminated structure. For example, it is also possible to adopt a structure in which glass, silicon or the like serves as a base material and the relay lines 23 are formed inside it.

In a wiring substrate, a wiring structure called a patch may be embedded in order to achieve high integration of some of wirings according to an electronic component to be mounted (for example, see Japanese Patent Application Laid-Open Publication No. 2014-236188 (paragraph [0044] and FIG. 1)).

However, a degree of high integration required for a wiring structure and an extent of high integration (that is, an area of an upper surface of a wiring structure) differ depending on the type of electronic component. A wiring substrate according to an embodiment of the present invention is capable of accommodating multiple types of mounted components having different requirements for high densification.

A wiring substrate according to one aspect of the present invention includes: multiple wiring structures that internally incorporate multiple relay lines, with both ends of the multiple relay lines exposed on an upper surface as multiple connection points; and a cavity that accommodates the multiple wiring structures. The multiple wiring structures include two or more types of wiring structures: a first wiring structure with a lower part being a silicon layer; a second wiring structure with a lower part being a glass layer; and a third wiring structure with a lower part being a resin layer and not including a glass layer or a silicon layer. The two or more types of wiring structures differ at least in planar size or in minimum L/S of the multiple relay lines.

Obviously, numerous modifications and variations of the present invention are possible in light of the above teachings. It is therefore to be understood that within the scope of the appended claims, the invention may be practiced otherwise than as specifically described herein.

1. A wiring substrate, comprising:
a wiring substrate having a cavity; and
a plurality of wiring structures accommodated in the cavity of the wiring substrate and comprising at least two of a first wiring structure, a second wiring structure and a third wiring structure such that the wiring structures include a plurality of relay lines internally incorporated and having a plurality of connection points exposed on upper surfaces of the wiring structures at end portions of the relay lines,
wherein the first wiring structure includes a silicon layer in a lower part of the first wiring structure, the second wiring structure includes a glass layer in a lower part of the second wiring structure, the third wiring structure includes a resin layer and does not include a glass layer or a silicon layer in a lower part of the third wiring structure, and the at least two of the first, second and third wiring structures differ in at least one of planar size and minimum L/S of the relay lines.

2. The wiring substrate according to claim 1, wherein the wiring substrate has a multilayer structure comprising a first insulating layer, a first conductive layer, a second insulating layer, a second conductive layer, a third insulating layer, and a third conductive layer are sequentially laminated such that the cavity is penetrating through the second insulating layer and the third insulating layer.

3. The wiring substrate according to claim 1, wherein the plurality of wiring structures includes the first and second wiring structures formed such that the minimum L/S of the relay lines and the planar size decrease in an order of the first and second wiring structures.

4. The wiring substrate according to claim 1, wherein the plurality of wiring structures includes the second and third wiring structures formed such that the minimum L/S of the relay lines and the planar size decrease in an order of the second and third wiring structures.

5. The wiring substrate according to claim 1, wherein the plurality of wiring structures includes the first and third wiring structures formed such that the minimum L/S of the relay lines and the planar size decrease in an order of the first and third wiring structures.

6. The wiring substrate according to claim 1, wherein the plurality of wiring structures includes the first, second and third wiring structures formed such that the minimum L/S of the relay lines and the planar size decrease in an order of the first, second and third wiring structures.

7. The wiring substrate according to claim 1, wherein one of the first, second and third wiring structures is a wiring structure having a first array region in which the connection points are formed in a matrix pattern and configured to be connected to a plurality of pads of a first electronic component, and a second array region in which the connection points are formed in a matrix pattern with a same pitch as the connection points in the first array region and configured to be connected to a plurality of pads of a second electronic component.

8. The wiring substrate according to claim 1, wherein the plurality of wiring structures is formed such that the connection points are formed in a matrix pattern and that the wiring structures having at least one of different planar size and different minimum L/S of the relay lines have different pitches of the connection points.

9. The wiring substrate according to claim 1, further comprising:
an electronic component having a plurality of pads formed on a surface thereof such that the plurality of pads is formed at positions overlapping the connection points of the at least two of the wiring structures and is configured to be connected to the connection points of the at least two of the wiring structures.

10. The wiring substrate according to claim 2, wherein the plurality of wiring structures includes the first and second wiring structures formed such that the minimum L/S of the relay lines and the planar size decrease in an order of the first and second wiring structures.

11. The wiring substrate according to claim 2, wherein the plurality of wiring structures includes the second and third wiring structures formed such that the minimum L/S of the relay lines and the planar size decrease in an order of the second and third wiring structures.

12. The wiring substrate according to claim 2, wherein the plurality of wiring structures includes the first and third wiring structures formed such that the minimum L/S of the relay lines and the planar size decrease in an order of the first and third wiring structures.

13. The wiring substrate according to claim 2, wherein the plurality of wiring structures includes the first, second and third wiring structures formed such that the minimum L/S of the relay lines and the planar size decrease in an order of the first, second and third wiring structures.

14. The wiring substrate according to claim 2, wherein one of the first, second and third wiring structures is a wiring structure having a first array region in which the connection points are formed in a matrix pattern and configured to be connected to a plurality of pads of a first electronic component, and a second array region in which the connection points are formed in a matrix pattern with a same pitch as the connection points in the first array region and configured to be connected to a plurality of pads of a second electronic component.

15. The wiring substrate according to claim 2, wherein the plurality of wiring structures is formed such that the connection points are formed in a matrix pattern and that the wiring structures having at least one of different planar size and different minimum L/S of the relay lines have different pitches of the connection points.

16. The wiring substrate according to claim 2, further comprising:
an electronic component having a plurality of pads formed on a surface thereof such that the plurality of pads is formed at positions overlapping the connection points of the at least two of the wiring structures and is configured to be connected to the connection points of the at least two of the wiring structures.

17. The wiring substrate according to claim 3, wherein one of the first, second and third wiring structures is a wiring structure having a first array region in which the connection points are formed in a matrix pattern and configured to be connected to a plurality of pads of a first electronic component, and a second array region in which the connection points are formed in a matrix pattern with a same pitch as the connection points in the first array region and configured to be connected to a plurality of pads of a second electronic component.

18. The wiring substrate according to claim 3, wherein the plurality of wiring structures is formed such that the connection points are formed in a matrix pattern and that the wiring structures having at least one of different planar size and different minimum L/S of the relay lines have different pitches of the connection points.

19. The wiring substrate according to claim 3, further comprising:
an electronic component having a plurality of pads formed on a surface thereof such that the plurality of pads is formed at positions overlapping the connection points of the at least two of the wiring structures and is configured to be connected to the connection points of the at least two of the wiring structures.

20. The wiring substrate according to claim 4, wherein one of the first, second and third wiring structures is a wiring structure having a first array region in which the connection points are formed in a matrix pattern and configured to be connected to a plurality of pads of a first electronic component, and a second array region in which the connection points are formed in a matrix pattern with a same pitch as the connection points in the first array region and configured to be connected to a plurality of pads of a second electronic component.
